(19) United States
(12) Patent Application Publication
(10) Pub. No.: US 2018/0038318 A1
(43) Pub. Date: Feb. 8, 2018

(54) WATER CAPTURE SYSTEM, ELECTROLYSIS CELL AND INTERNAL COMBUSTION ENGINE KIT

(71) Applicant: EMISSION TECHNOLOGIES INTERNATIONAL LIMITED, TORONTO (CA)

(72) Inventor: WILLIAM (BILL) JAMES ROSS, EAST GWILLIMBURY (CA)

(21) Appl. No.: 15/229,723

(22) Filed: Aug. 5, 2016

(51) Int. Cl. F02M 25/022; F02M 26/35; H01L 35/32; C25B 1/04; C25B 9/06; F01N 3/02; B01D 53/26

(52) U.S. Cl. CPC F02M 25/0222; F01N 3/0205; F02M 26/35; F02M 25/0224; F02M 25/0227; B01D 53/265; C25B 1/04; C25B 9/06; H01L 35/32

(57) ABSTRACT

An electrolysis cell and internal combustion engine kit are provided in which water for the cell may be captured such as from engine exhaust. Water feeding from a water condenser to a water tank and from the water tank to the cell is pump free. Peltier type thermocouples are configured to provide cooling or heating for enhanced operations. Conductive level detectors detect fluid levels in various vessels of the electrolysis system.

### FIELD

The present matter relates generally to improving efficiencies of combustion engines and more particularly to a water capture system, an electrolysis cell and an internal combustion engine kit as well as components therefor.

### BACKGROUND

Four stroke internal combustion engines release pollution and suffer inefficiencies in fuel combustion, particularly at idle. Some engine applications, particularly for motorized vehicles, can spend 40% or more of their active live in the idle state. It is desired to improve engine efficiency and reduce the emission of pollution.

### SUMMARY

An electrolysis cell and internal combustion engine kit are provided in which water for the cell may be captured such as from engine exhaust. Water feeding from a water condenser to a water tank and from the water tank to the cell is pump free. Thermocouples (e.g. Peltier) are configured to provide cooling or heating for enhanced operations. Conductive level detectors detect fluid levels in various vessels of the electrolysis system. Additional components are also described.

There is provided an engine exhaust water recovery system comprising: an exhaust receiving and cooling segment configured for fluid coupling to an exhaust manifold to receive exhaust gas from an engine; an exhaust water condensing unit in selective fluid coupling with the exhaust receiving and cooling segment to selectively receive exhaust gas; an exhaust discharging segment in selective fluid coupling with the exhaust receiving and cooling segment and the exhaust condensing unit to selectively receive exhaust gas for discharge from the engine exhaust water recovery system; and a control unit to control the selective receiving of exhaust gas to produce water in the exhaust condensing unit.

The exhaust discharging segment may be configured for fluid coupling with an intake of the engine to discharge the exhaust gas back to the engine. The exhaust water condensing unit may comprise a water feed passage to discharge water condensed by the exhaust condensing unit. The exhaust water condensing unit may comprise a fluid inlet configured for fluid coupling to a evolving gas outlet of an electrolysis cell generating combustion enhancing gas the combustion enhancing gas pressurizing the exhaust condensing unit to discharge water through the water feed passage under control of the control unit.

The water feed passage may be in fluid coupling with a water tank to store water to feed the electrolysis system. The water feed passage may discharge the water to a filtration system to filter the water for the water tank.

The engine exhaust water recovery system of claim 1 may have a first solenoid to selectively control, via the control unit, a delivery of exhaust gas from the exhaust receiving and cooling segment to the exhaust water condensing unit. And may have a second solenoid to selectively control, via the control unit, a delivery of exhaust gas from the exhaust water condensing unit to the exhaust discharging segment.

The engine exhaust water recovery system may have a drain in selective fluid communication with the water feed passage of the exhaust water condenser unit and a third solenoid to selectively control, via the control unit, a discharge of water from the exhaust water condensing unit through the drain. The exhaust condensing unit may have a level detector, in communication with the control unit, to detect a level of water in the exhaust water condensing unit. The exhaust receiving and cooling segment may comprise a stainless steel pipe having a coiled portion. The exhaust receiving and cooling segment may have a stainless steel pipe with an engine mounting end for fluid coupling to the exhaust manifold using a brass fitting.

There is provided a system for producing one or more gases for enhancing combustion in an internal combustion engine, said engine having an intake, the system comprising: an electrolysis cell, to generate one or more combustion enhancing gases from an electrolytic solution; a gas conduit, to connect the electrolysis cell to the intake of the internal combustion engine; a water tank, having a tank discharge port in fluid coupling with the electrolysis cell, to hold water to replenish the electrolysis cell; a water recovery system, in fluid coupling with the water tank, to generate water to replenish the water in the water tank; and a control unit to control power to the electrolysis cell to control the generating of the one or more combustion enhancing gases, and to control the respective replenishment of water by water tank and the water recovery system.

The water recovery system may be an engine exhaust water recovery system in fluid coupling with an exhaust manifold of the internal combustion engine. The system may comprise a pressure connection between the electrolysis cell and the engine exhaust water recovery system wherein a positive pressure from the one or more combustion enhancing gases selectively drives water from the engine exhaust water recovery system to replenish the water tank under control of the control unit. The engine exhaust water recovery system may be in fluid coupling with the gas conduit to provide exhaust gas with the combustion enhancing gases to the intake.

The electrolysis cell may have a level detection system in communication with the control unit to control an operation of the electrolysis cell, including to replenish water. The level detection system may comprise a plurality of level detectors extending into the electrolysis cell, through a top of the cell, and to respective lengths below the top, the plurality of level detectors each electrically detecting a respective amount of the electrolytic solution in the electrolysis cell using electrical current. At least one of the level detectors may comprise a wire having a diode and a terminal. The wire may be over moulded with a plug in sealing engagement with the wire, the, plug configured to fasten the level detector to the top of the cell. The level detectors may be electrically coupled to automotive relays to provide respective level signals to the control unit.

The system may further comprise a cell condenser, in fluid communication with the electrolysis cell and the gas conduit, to condense electrolytic fluid from the combustion enhancing gases and return the electrolytic fluid to the electrolysis cell.

The electrolysis cell may comprise: a first electrode comprising a cylindrical body; a second electrode comprising a cylindrical body within the first electrode; and a first electrode extension electrically coupled to the first electrode and coiled about and spaced from the second electrode. The electrode extension and second electrode may comprise mesh bodies of expanded metal. The electrolysis cell may further comprise a top cap and a bottom cap in sealing engagement about ends of the first electrode to define a containment body for the electrolytic solution. The electrolysis cell may further comprising insulating spacers separating the coils of the first electrode extension and separating the first electrode extension from the second electrode.

In the system, the water tank may comprise a filter system to filter the water received from the water recover system. The filter system may comprise a series of filters defining a replaceable cartridge. The water tank may be positioned vertically above the electrolysis cell to replenish the cell via a gravity feed line. The system may comprise at least one Peltier-type thermocoupling adjacent the water tank to heat the discharge port and/or the gravity feed line. A plurality of Peltier-type thermocouplings may be mounted about the electrolysis cell to generate power from heat generated by the electrolysis cell. The plurality of Peltier-type thermocouplings mounted about the electrolysis cell may be electrically coupled to provide power to the at least one Peltier-type thermocoupling adjacent the water tank for heating.

There is provided an electrolysis cell, to generate gases from an electrolytic solution, comprising: a first electrode comprising a cylindrical body; a second electrode comprising a cylindrical body within the first electrode; and a first electrode extension electrically coupled to the first electrode and coiled about and spaced from the second electrode.

The electrolysis cell may further comprise a top cap and a bottom cap in sealing engagement about ends of the first electrode to define a containment body for the electrolytic solution. The electrolysis cell may further comprise a plurality of level detectors extending into the electrolysis cell and to respective lengths below the top cap, the plurality of level detectors each electrically detecting a respective amount of the electrolytic solution in the electrolysis cell using electrical current. The electrolysis cell may comprise a water fill tube extending into the containment body and configured for coupling to a feed line to selective receive water to replenish the electrolytic solution. The electrolysis cell may comprise a primary outlet and a vent outlet to a cell condenser, wherein the primary outlet is selectively open and the vent outlet selectively closed under normal operation of the electrolysis cell to provide gases to the cell condenser and wherein the primary outlet is selectively closed and the vent outlet selectively open to receive water to replenish the electrolytic solution.

### BRIEF DESCRIPTION OF THE DRAWINGS

The present matter may be further understood by reference to following description in conjunction with the appended drawings in which:

FIG. 1 is a diagram illustrating components of a self-contained electrolysis system, in accordance with an example;

FIG. 2 is a side elevation of selected components of FIG. 1 including an electrolysis cell and a cell condenser, in accordance with an example, where a side of the electrolysis cell is cut away to show an interior thereof;

FIG. 3 is a top view of the electrolysis cell of FIG. 3 along the lines 4-4, accordingly to an example;

FIG. 4 is a top view of a portion of an electrolysis cell mounted with a plurality of heating devices on a support plate, in accordance with an example;

FIG. 5 is a side elevation of a filter system, water tank and Peltier liquid gas control (PLGC), in accordance with an example, where a side is cut away to show an interior thereof; and

FIG. 6 is a sectional view of a PLGC, in accordance with an example.

In the following description like numerals refer to like structures and process in the diagrams.

### DETAILED DESCRIPTION

Electrolysis cells and systems comprising electrolysis cells for combustion engines include U.S. Pat. No. 7,143,722 issued Dec. 5, 2006 and entitled “Electrolysis cell and internal combustion engine kit” and U.S. Pat. No. 6,896,789 issued May 24, 2005 and entitled “Electrolysis cell and internal combustion engine kit”. Both of these US patents are incorporated herein by reference.

In brief, electrolysis systems and cells use an electrolysis process to break down hydrogen and oxygen from water. An electrolysis cell has three main components, namely, an electrolytic solution of water and ions (e.g. Na or K ions), an anode and a cathode. An external electrical potential (i.e. voltage) of correct polarity and sufficient magnitude is applied to the anode and cathode which are in contact with the electrolyte solution such that the normally stable solution decomposes. That is, the H₂O molecule in particular breaks down. The extracted hydrogen and oxygen atoms are provided to the intake of a combustion engine to improve its efficiency.

Water from the electrolytic solution is consumed during the process and may be replaced such as from a water tank of the electrolysis system. However, over time, a water tank may deplete and require re-filling. Users of such systems may forget to fill the tank or not have water available when it is needed. A self-sufficient water supply is desirable.

Further, a many electrolysis systems are installed on vehicles or used in other environments subject to low temperatures, water in the water tank may freeze, particularly when the engine is not in use. For example, vehicles are often parked over night and shut off and cold ambient temperatures may freeze water. Though electrolyte solutions often have a lower freezing point than water, such solutions may also partially freeze in a cell in severe weather conditions at −60 to 80° Celsius. With these extreme temperature differentials, a busman fusible link may be used to pulse amperage to control the power supply until enthalpy increases or gas production begins evolving through any ice crystals.

The “Electrolysis cell and internal combustion engine kit” of U.S. Pat. No. 7,143,722 and U.S. Pat. No. 6,896,789 show an electrolysis cell, a cell condenser, electrolysis cell fill floats and a user fillable water tank in certain configurations. Disclosed herein are improvements thereto including: an electrolysis cell configuration; a cell heater which also generates power when the cell is operating, electrical cell fill detectors; a self-sufficient water system to capture water such as from engine exhaust to a water tank; a tank heater; among other features described herein below.

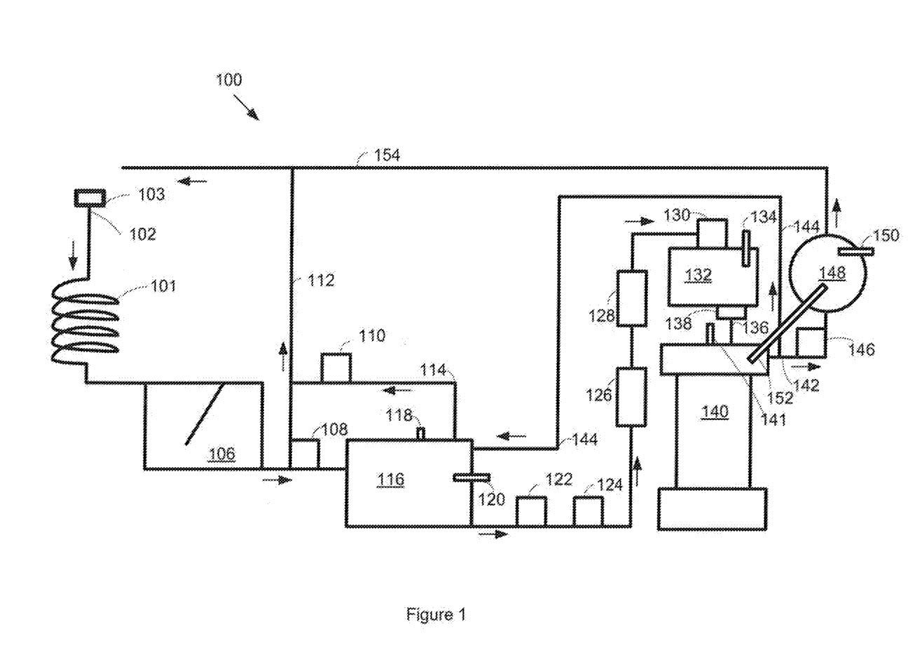

FIG. 1 is a diagram illustrating components of a modular electrolysis system 100, in accordance with an example. Modular electrolysis system 100 may be provided as a kit for installation such as on a vehicle (bus, truck, etc.) System 100 includes a water capture system to obtain distilled water from engine exhaust to fill a water tank, thus avoiding a user having to fill the tank.

System 100 comprises a stainless steel coiled pipe 101 for coupling to an exhaust manifold of a vehicle (both not shown). The pipe 101 may comprise ½ inch (12.7 mm) stainless steel pipe with 4-5 coils approximately 5 feet (1.524 m) in total length. The pipe may be connected to the manifold at pipe end 102 via a brass to cast iron fitting 103. In a retrofit installation, for example, a hole may be drilled in a side of the exhaust manifold and the pipe 101 coupled using the fitting 103. The fitting 103 accounts for temperature differentials and expansion and contraction rates for the stainless steel pipe and cast iron manifold. By extracting exhaust gas at its hottest exit point, obtaining condensation is easier. The drilling may be performed to lessen impact on any downstream catalytic converters, for example, capturing drilled iron waste using a magnet.

Corrugated thin wall standard gas stainless steel pipe 101 feeds exhaust gas to exhaust condenser 106. From exhaust condenser 106 output is feed through a 3-way exhaust solenoid 108 (a selective or switchable valve having three positions) for delivery back via an exhaust gas intake feed 112 (one or more hoses, etc. forming a gas conduit) or to a water condenser 116. Water condenser 116 operates to condense water from the exhaust gases that have been cooled via coil 101 and (partially) condensed in gas condenser 106. Solenoid 108 feeds water condenser 116 selectively, such as when water is needed to top up water tank 132 as described further. Gases from water condenser 116 are returned via output line 114 to 2-way solenoid 110 (a selective or switchable valve having two positions), which is normally open when water condenser 116 is receiving gases from solenoid 108. Solenoids 108 and 110 are closed when water condenser 116 is activated to output water to fill the tank 132. To assist with this output, water condenser 116 is coupled to line 144 (a pressure connection) to receive a positive pressure (e.g. 3-5 pounds) from electrolytic cell 140 to drive the water with the evolving gas pressure from the water condenser 116 to a water tank 132.

Water condenser 116 has a pressure sensor 118 operable to detect pressure in the tank (e.g. sufficient pressure from electrolytic cell 140) which when achieved and water is required by the tank 132, the sensor output may be used to open the flow as described below.

Water condenser 116 further has a level system 121 to detect an amount of water in water condenser 116, for example to assist with control of water condenser signaling when solenoids 108 and 110 may be closed and when sufficient water is present to output toward the water tank 132. Water from water condenser 116 is output under control of a 3 way drain solenoid 122 and 3 way water feed solenoid 124. Pressure sensor 118 may be used to determine when to open the solenoids 122 and 124 to fill the water tank 132. When both solenoids 122 and 124 are open water may be output toward water tank 132 via a filter system such as cation filter 126, anion filter 128 and charcoal filter 130 to filter the distilled water. The cation and anion filters provide grease removing media and a polishing charcoal filter is provided at the end. The 3 filter system may be configured as a user replaceable component such as a cartridge for example. When solenoid 124 is closed and solenoid 122 is open, water condenser 116 may be drained. Both of these solenoids may open to drain the system for shut down in freezing applications

Water tank 132 has a level system 134 similar to level system 120. Level system 134 detects when water in tank 132 needs a top up and when it is full as described further below such that further filling is not required.

Water is output from tank 132 via line 136 to electrolysis cell 140. Water tank line 136 may be heated (e.g. selectively) by a Peltier Liquid Gas Control (PLGC) 138 having a Peltier-type thermocouple with hot side in as described further below.

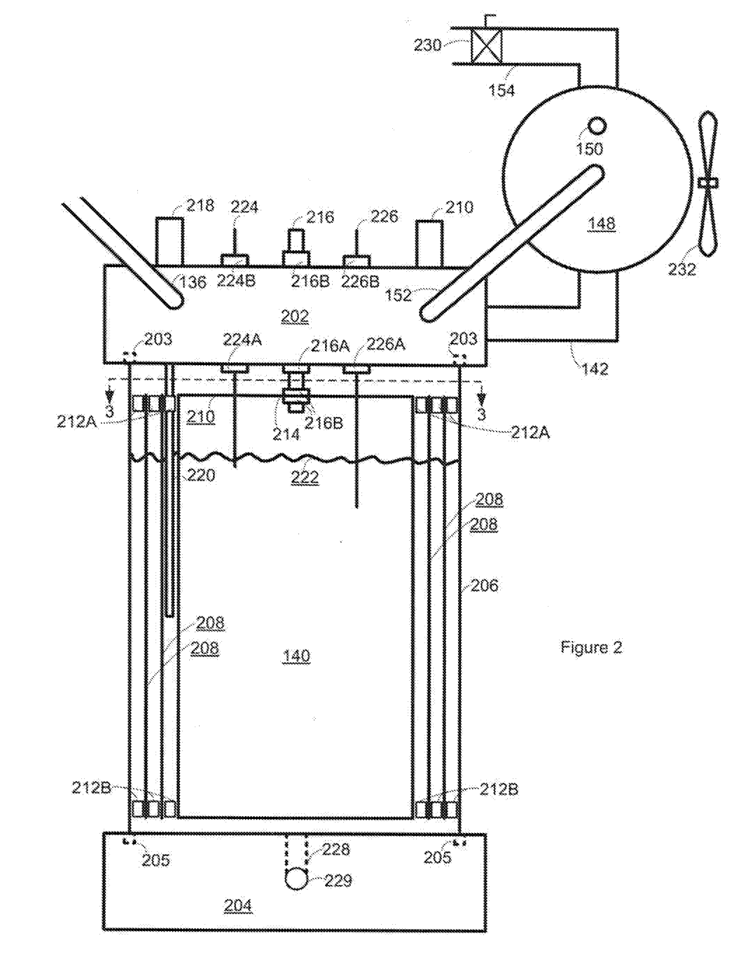

Electrolysis cell 140 receives water from tank 132 as the electrolytic solution is depleted, which depletion is detected by a level system 141 (see too, 224 and 226 of FIG. 2). Cell 140 is coupled to output combustion enhancing gases (e.g. hydrogen and oxygen) to a cell condenser 148 via pipe 142 and 3-way gas feed solenoid 146, when solenoid 146 is open. When solenoid 146 is closed, pressure connection 144 coupled to pipe 142 is pressured from the gases output from cell 140. This positive pressure may be directed to water condenser 116 when water is needed to top up tank 132.

Water tank 132 may be configured to provide water via gravity and cell 140 configured to receive water via gravity such as by mounting the water tank vertically above the cell 140. In this way, no pumps are necessary within system 100 to move water from condenser 116 through to cell 140. Alternatively, the tank reservoir can be mounted in a different configuration and operated with a gas pressure.

Gases from cell 140 may have entrained water and/or electrolyte solution vapour. Cell condenser 148 operates to condense the vapour in the gases received via line 142 and remove same before the gases are provided to the engine. Any condensate is returned to cell 140 such as by gravitational flow back though line 142. Cell condenser 148 has a level system 150 for detecting a level of water/liquid condensed from the gases received from cell 140. Further, cell 140 and cell condenser 148 are coupled via vent line 152, which may be open during a water fill operation to fill cell 140 to top up with water from tank 132. Cell condenser 148 provides output gases via pipe 154 to combine with exhaust gases from pipe 112 to feed the engine via its intake (not shown). Operation of cell condenser 148 is described further herein below.

Though not shown, the various solenoids, level systems, electrolytic cell anode and cathode (see FIG. 2), and heater(s) may be coupled to a processor e.g. CPU, PLC, PGA, etc.) for controlling operation of system 100. System 100 may be coupled for power such as from the engine system to which system 100 is also coupled to provide the gases. In the present example, a programmed CPU starts the system when engine rpm and voltage are detected. When level system 141 contact or voltage is removed a certain number of times using a detector indicating a low solution level or no voltage, applicable solenoids turn on to fill and vent the cell 140. Before the water from exhaust system initiates, the CPU checks for component compliance, fill system off or on, pressure, power supplies off or on, etc.

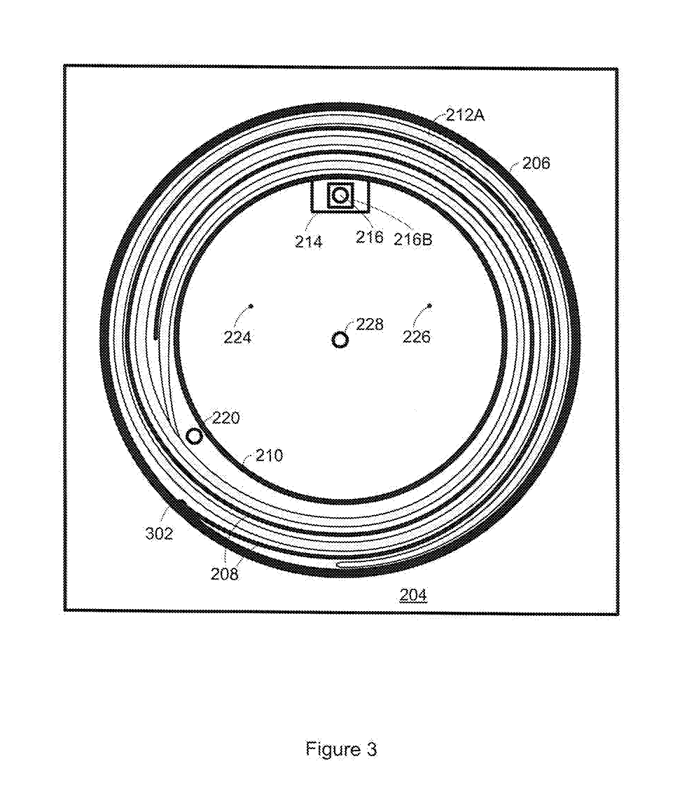

FIG. 2 is a side elevation of selected components of FIG. 1 including an electrolysis cell 140 and a cell condenser 148, in accordance with an example. A side of the electrolysis cell 140 is cut away to show an interior thereof. Reference may also be made to FIG. 3 which shows a cross section of FIG. 2 along lines 3-3. Cell 140 comprises a first or top end cap 202, a second or bottom end cap 204 and a first electrode 206. The components 202, 204 and 206 provide a containment body. The top and bottom end caps 202 and 204 may be formed from ultra-high molecular weight (UHMW) polyethylene or other suitable plastic or other material which is not reactive to the electrolytic solution and is sufficiently electrically non-conductive with no water absorption. In the present example, electrode 206 comprises a stainless steel or nickel, generally cylindrical pipe (e.g. a seemless schedule 10, 304L or 316L pipe). As described further, this pipe is configured as a component of an anode of the cell 140. Other materials such as impregnated ceramics (e.g. with nickel or stainless steel) or thermo-compounds may be employed. The cylindrical shape of the electrode 206 assists to straighten the travel of evolving electrons providing some production efficiencies.

Within the end caps 202 and 204 are cylindrical grooves 203 and 205 (shown in dotted lines) with EPDM o-rings to receive the cylindrical segment in sealing engagement. End cap 204 may have a drain passage 228 (in dotted lines) providing a channel through a top surface of cap 204 with a port 229 through a side surface (as shown) or a bottom surface (not shown).

An electrode extension 208 is electrically coupled to containment body electrode 206. In the present instance it is coupled by spot welding 302 (see FIG. 3). Electrode extension 208 is coiled within the first electrode 208. It may be an expanded metal, preferably made from an unalloyed metal (pure) and one that does not react with the electrolytic solution to plate or corrode the various electrodes in the solution. Nickel is preferred, such as nickel 200. Nobel metal may be used. Electrode extension 208 preferably is the same material as electrode 206. Electrode extension 208 may comprise perforations (not shown), such as slits cut in the metal prior to a stretching/expansion from opposite ends, creating diamond shaped holes from the slits. The electrode extension 208 may appear as a mesh.

A second electrode 210 (e.g. a cathode) is also provided in the body in the form of a cylinder. The cylindrical form may be an expanded metal. The body may have perforations (not shown), preferably cut in the body as described for the electrode extension 208. Electrode 210 is preferable made from an unalloyed metal (pure) and one that does not react with the electrolytic solution to plate or corrode the various electrodes in the solution. Nickel is preferred, such as nickel 200. Nobel metals may be used.

The degree to which the expanded metal for the electrode extension 208 or electrode 210 is stretched or expanded is expressed as a percentage of open surface area relative to total surface area. Therefore, a metal designated as 50% expanded has openings or holes over 50% of the surface and metal over the other 50% of the surface. There is usually a tradeoff in that a higher degree of expansion creates more edges, which is desirable, but also results in thinner metal which is weaker and generates more heat. In the preferred embodiment it has been found that nickel expanded to a maximum of 50% produces adequate results. However it can be appreciated that as newer metallurgical techniques are developed, adequate results may also be available from nickel or other metals that are expanded by more than 50%.

The electrode extension is spaced from itself and electrode 210 with insulation such as Teflon shown as spacers 212A and 212B and also seen in FIG. 3. The insulation (spacer) is over approximately ½ inches (12.7 mm) of the extension electrode 208 with one spacer band at the top end and one spacer band at the bottom end of the extension 208. The insulations spaces the coils by about 3 mm from one another and the electrode 210. The second electrode 210 and electrode extension 208 are sized to extend short of end cap 204 to permit an electrolytic solution to flow into the interior of the second electrode 210 as well as about the electrode extension 208 via the gaps. It is understood that the position of the anode and cathode may be reversed such that the cathode is the external or first electrode and the anode is the internal or second electrode pipe, with polarities reversed.

The first electrode 206 is coupled to positive or anode power such as via a gear clamp (not shown). The pipe is insulated from the clamping assembly, which is grounded. Second electrode 210 is coupled for power via coupling 214 that is attached to a negative or cathode terminal 216. The terminal may be a nickel threaded rod with a ¼ inch (6.35 mm) nylon plug (216A) to fit into a bottom side of top end cap 202. A pair of nickel nuts (216B) may also be used to attach the threaded body of the terminal 216 to coupling 214.

Water fill pipe 136 fills containment body 206 via a solenoid 218 and interior fill, pipe 220 to add to electrolyte solution therein. The electrolyte solution is represented by line 222. Cell 140 has a level system 141 including full level detector 224 and fill or low stop level detector 226 that extend though cap 202 to respective lengths within the containment body to electrically detect respective amounts of electrolytic solution within the cell.

The relative length between the full level detector and fill or low stop level detector determines how much water is to be added. The length of the fill level detector determines when water should be added. If insufficient solution is in cell 140 and it cannot be topped up from water tank 132 detectors 224/226 act as a stop detector, providing input to a processor to stop operation of the electrolysis cell by power off (e.g. removing power to the electrode 206/208).

Detector 150 of cell condenser 148 is a full stop detector. If a sufficient signal is received from detector 150 then too much electrolytic solution is present in condenser 148 and operation of cell 140 should be stopped.

In one example, first electrode 206 is approximately 4.5×10 inches (114.3 mm×254 mm) in size holding approximately 1700 ml of electrolyte solution comprising 33% by weight KOH and distilled water. This volume is sufficient to produce evolved gases for an engine of 7-14 liters (L) engine displacement. Detectors 224 and 226 may be configured to trigger a top up of water of approximately 20 ml when the solution is partially depleted by such an amount. Though only a single cell 140 is shown, additional cells may be used for larger engines.

The level detectors 224 and 226 may comprise a wire (e.g. nickel) of sufficient length to extend through top cap 202 into the containment body to the required position. The outside end of the wire may have a 3 mA diode and a ¼ inch (6.2 mm) male spade terminal (both not shown). The wire may fit into an under surface of top cap 202 using a ⅛ inch (3.175 mm) over moulded nylon or other plug (respectively 224A, 225A and 226A) in sealing engagement with the wire. After installation, the upper surface of cap 202 may be topped off with a J-B weld as an extra seal (e.g. 224B and 226B). Level detection and additional construction is described further below. The level systems in other vessels herein (e.g. cell condenser, water tank, water condenser) may comprise detectors of similar construction. As the electrode terminal 216 is a threaded body, a stainless steel, flat washer with a ⅜×¼ EPDM o-ring and nut 216B may complete installation on the topside of cap 202.

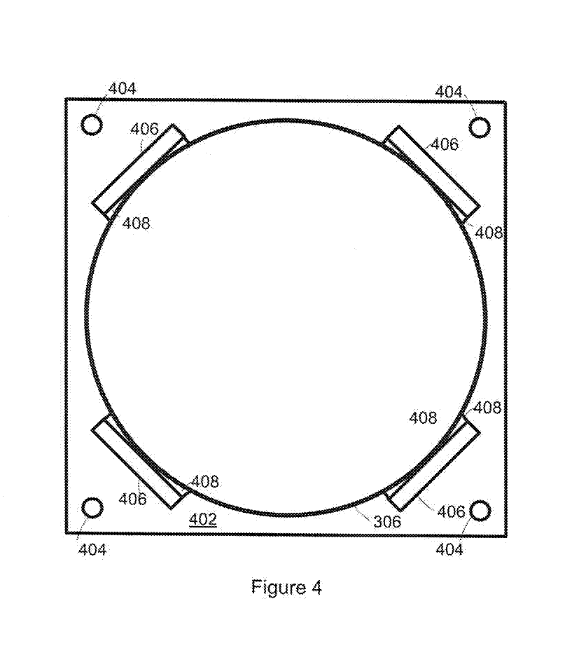

FIG. 4 is a top view of first electrode 206 of electrolysis cell 240 mounted with a plurality of Peltier devices 406 (e.g. TEC1-12706, available from a variety of manufacturers) on a support plate 402, in accordance with an example. Support plate may comprise a stainless steel material, ¼ inch (6.3 mm) thick and have mounting holes 404 through which fasteners may be secured to mount support plate 402 to bottom end cap 204. Peltier devices 406 are mounted cold side to the pipe of electrode 206. In the top view of FIG. 4, four heating devices 406 are shown; however, three additional heating devices 406 may be stacked vertically and in series with each of the four shown, for example, to comprise 16 in total. The Peltier devices 406 may be mounted to the pipe using a thermo compound and be controlled via hermitically sealed thermocouple (e.g. temperature reactive switch configured to operate at a temperature threshold) to start Peltier liquid gas control.

With the cell up and running, the amps and voltage produced by these Peltier devices can be directed to power a Peltier liquid gas control connecting the cell 140 to the water tank 132 to heat same in freezing environments. In warm environments, the Peltier liquid gas control need not be used or installed. A HDPE hose (line) could be employed without a heater. The Peltier liquid gas control does not require a ground with media electrical insulation from the conductive material used for the body of the device to prevent any possibility of an event from static electricity.

Any (distilled) water supply or tank connected in this manner could have a drop in filter system (e.g. filter cartridge having three filters 126, 128 and 130 as described). While the figures herein show a water system obtaining distilled water from exhaust, a user tillable tank could be employed. A water tank such as 132 need only store a small volume of water (e.g. 100 ml) if it is receiving water from a capture system but may be larger (e.g. 3-4 L). A small water tank holding a low volume of water is more easily heated in cold temperatures. A capture system such as shown can easily capture sufficient water to fill the water tank during 5 hours of engine running for example.

Further with respect to FIG. 2, cell condenser 148 provides the evolved gases to the engine though a check valve 230. Cell condenser 148 may be temperature modulated by a fan 232 passing ambient air to assist to bring the gases to a dew point temperature. Though not shown herein but shown in U.S. Pat. No. 7,143,722, for example, a modular system 100 may be configured to have many of its components housed in a cabinet (e.g. each or most of each of components 140-150 of FIG. 1).

For pressure containment and safety purposes, though not shown, cell 140 may be reinforced and constructed to pressure vessel standards (e.g., ASME B31.1) such as by various containment rods and other hardware as shown in U.S. Pat. No. 7,143,722.

Filter System, Water Tank and PLGC

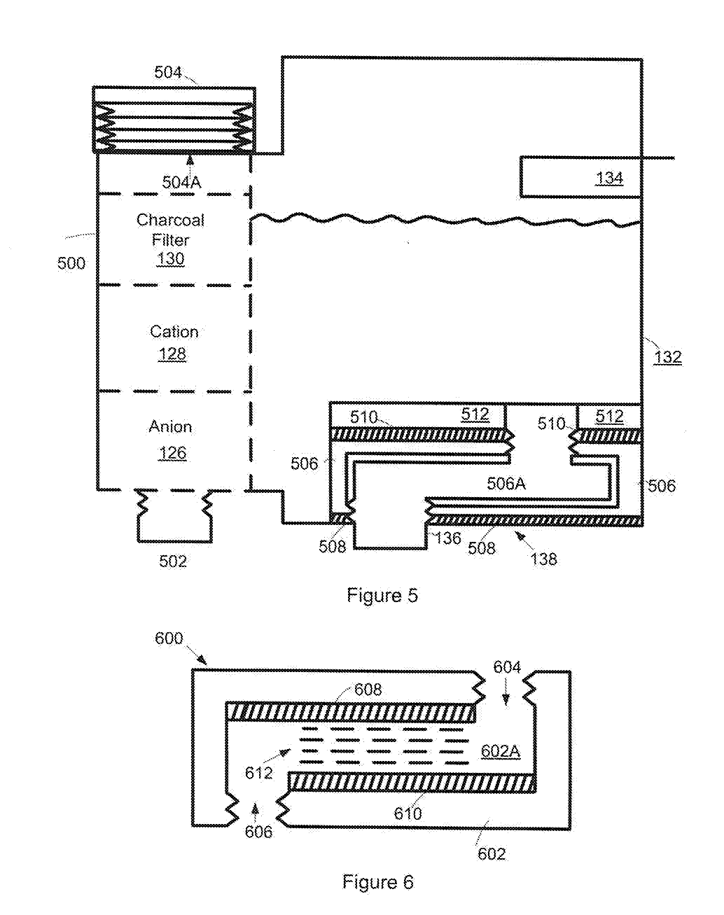

FIG. 5 is a side elevation of a filter system 500, water tank 132 and PLGC 138, in accordance with an example, where a side is cut away to show an interior thereof. It is understood that other configurations are possible within system 100 or other uses.

Water tank 132 and filter system 500 are configured as a combined unit such that the filter system 500 outputs directly into the tank 132. Filter system 500 has an input 502 (which may be threaded to receive a line (pipe or hose, etc.) and filters 126, 128 and 130 as previously described. Input 502 may receive water such as from a line from condenser 116. The top end of the filter system 500 has a screw cap 504 topped opening 504A for access to replace filters 130, 128 and 126, which may be configured as a cartridge for example.

At a bottom of tank 132 (or otherwise adjacent to it), about a discharge port 132A for a gravity feed line (e.g. 136) to cell 140, there is shown a PLGC 138 in which a body 506 defines a chamber 506A passing through the body having Peltier thermocouples 508 and 510 lining the chamber (e.g. surrounding at least a segment thereof), hot side in. The body may be formed of any conductive ceramic or any conductive metal with an insulation. The thermocouples may be mounted using a thermo compound adhesive. The thermocouples may be mounted about the port 132A or the gravity feed line 136 or both. Above the PLGC 138 is a heating pad 512, which pad may be used in extreme cold.

On the application of power to a Peltier device, the device operates to provide a hot side and a cold side. Also, such devices may generate power when there is a substantial ambient temperature differential across the two sides Peltier devices 406 around cell 140 may be externally powered to heat the cell 140. However, when cell 140 is operating and evolving gases, it releases significant heat which generates a sufficient temperature differential to cause Peltier devices 406 to generate power. The power therefrom may be directed to PLGC 138 to activate same and heat water tank 132 such as when the ambient temperature is below a threshold (e.g. −10° C.)

Level system 134 may also provide temperature information for example to operate a draining on shutdown or to operate PLGC.

FIG. 6 is a sectional view of a PLGC 600, in accordance with an example. There is a body 602 having a passage 602A with an input opening 604 and output 606. Within and along at least most of the passage are Peltier-type thermal couples (608, 610) placed cold side in. The thermocouples may be mounted using a thereto compound adhesive. The body may be conductive ceramic or metal to define a cooling chamber. The input 604 and output 606 may be threaded (e.g. ¼ NPT). A 0.500 inch (12.7 mm) hole or 0.062 inch (1.5748 mm) grooved profile 612 is provided to conduct temperature for the water or gas across the Peltiers.

A PLGC like 600 may be connected between the 3-way exhaust solenoid 108 and water condenser 116 on the exhaust water recovery system. PLGC 600 may be coupled electrically to Peltier devices 406 about cell 140 to receive power. The cooling chamber can be conductive ceramic (no ground required) or a metal (ground required) that does not contaminate the water. PLGC 600 may be used to help bring the exhaust gas to the dew point in installations where space does not allow for the condensing coil of pipe 102 or where the system 100 is to operate in high temperature climates.

Filling Process for Alkaline or Acid Electrolyte Electrolysis Cell

Electrolyte level and consistency are maintained with a hose or pipe 136 connected to the water input on the cell's top cap 202 or similar location. Interior fill pipe 220 is sized to extend down and through the electrolyte to about to the middle of the containment body. If the water just dropped on top of the electrolyte, the level detectors 224 226 would not sense a signal because the water would tend to float on top of the denser electrolyte for a time, giving it a false, low specific gravity or PH # and very little current carrying capacity for level detection

Evolving gas creates a conductive froth or foam of bubbles about 1-2 inches (22.5-45 mm) high depending on the electrolyte level, temperature, contamination, pressure and density. This foam/froth will always create false level detection readings especially in stationary applications. The distance between the level detectors take these false readings within this about 1-2.5 inch (22.5-63.5 mm) space into account for filling and stopping the cell before the electrolyte solution, density level goes below a critical point.

When the density of the electrolyte solution is too low, the KOH (or other salt used in the solution) starts to solidify and form a salt bridge which will cause a short between the electrodes of the anode and cathode. In the interior water fill tube 220, a small amount of hydrogen and oxygen gas may become trapped by the closed solenoid (218), the trapped gas will push up through the water feed tube 220 on fill start when solenoid 218 opens. This serves two purposes, clearing the path for filling, and leaving trace amounts of electrolyte solution in the water tank 132 to slow freezing. Alternatively, this gas can be vented back into the cell 140 by allowing the solenoid 218 to equalize pressure through a feed (not shown) into the cell 140.

Level Detection and Detector Construction

Through extensive testing including millions of on road miles at various temperature extremes, floats, witches and optical sensors, are subject to failure.

Hydrogen being one of the smallest atoms will migrate along with some moisture into any plastic or metal type float. It has been found after one year or less with North American temperature extremes that these type of floats will gain weight and fail. This happens because the electrolysis cell has a hot hostile strong alkaline or acidic electrically charged process chamber, where a very large number of excited hydrogen and oxygen atoms are evolving.

Optical sensors have problems with the changing density and clouding inside their protective tube giving false readings

Level detectors using rods and square waves also become contaminated and bridged over time and temperature extremes, which can cause catastrophic failure.

The level detectors described herein are simple, economical, long lasting, maintenance free nickel level devices. They are reliable and can be made with thick nickel wire for high pressure applications.

As noted previously, nickel wire is used with an over-moulded plug. The second electrode terminal 216 may comprise a nickel rod body with over moulded nylon plug. The plugs preferably have a National Pipe Thread Taper (NPT). Level detectors may have ⅛ inch (3.175 mm) size and the terminal a ¼ inch (6.3 mm) size for the plugs.

Three moulded level detectors are required for each generator (electrolysis cell and cell condenser) along with one moulded electrode terminal.

The diameter of the nickel wire for each detector 224 226 and 150 can be no smaller than 0.047 inches (1.1938 mm) but can increase to a popular size or bigger for stability in a pressured electrolysis cell. The wire may be nickel 200. The nickel 200 threaded rod for the electrode terminal 216 can be any popular size above 0.187 inches (4.7498 mm) and two nickel 200 nuts (216B) may be used for each rod (to attach to the electrode (e.g. cathode 210).

The nylon is moulded to the nickel because the hydrogen atom and will leak through any opening not bubble tight. The ¼ inch (3 mm) spade terminal on the wire of a level detector is crimped and soldered or spot welded to the nickel wire to maintain the crucial small electrical flow for level sense. A diode connected to each level detector to prevent the level detectors from acting as anodes and being contaminated. In cell 140, the level detectors 224, 226 are separated and insulated through the top cap 202. The level detectors may be electrically coupled to standard automotive relays (not shown), which in turn may be used to signal the CPU. Electrically coupling the detectors to optoisolators (inputs) in the CPU may be insufficient to provide proper signaling due to fluctuations (transient polarity and voltage) in the cell 140 environment experienced by the detectors. The signals from the detectors are sufficient to trigger standard automotive relays.

The level detectors 224, 226 in the cell pick up a negative charge from the electrolyte solution in the cell 140 when they are operational. The tip of the nickel rod contacts the electrolyte sending a voltage to the terminal 86 on standard automotive relays, which power up. The signal tells the CPU what state of level the cell is in (low, full, too full (from detector 150)) and it reacts accordingly. A high level stop (from detector 150) will activate anytime the electrolyte contacts the rod because it is constantly grounded. Preferably, only trained personnel can restart the unit in such a case.

During the electrolysis reaction, the detection signal must pass through the foam or fog in the electrolyte to achieve ground, which, will cause transient signals. Any engine movement will cause sloshing which will cause intermittent detection, which will end once maximum full is reached.

False readings will not excessively stop and start the electrolysis cell 140, because the CPU registers a number of start fill signals before activating and will stay on a set length of time. Without this program, if the cell 140 is mounted on any mobile application, sloshing would stop and start the cell numerous times before it is full, reducing the gas output and efficiency of the cell.

Low level or stop detector 226, when contacting the fog, foam or electrolyte will provide a ground to C1-86 powering C1-87 and signaling the CPU this is one of the conditions to start and operate the cell 140. The full detector 224 when contacting the fog, foam or electrolyte will provide a ground to C1-86 powering C1-87 and signaling the CPU this is one of the conditions to start and operate cell 140.

When the electrolyte level along with foam or fog are reduced through gas production and contact is lost with the full level, this stops the ground to C1-86 losing power to C1-87, signaling the CPU to turn off the power supply to the anode 206.

The CPU will activate the vent solenoid 210 and fill solenoid 218 to cause a fill from the water source (e.g. 132). Once the cell 140 is venting via 152, with the water solenoid 218 open, gravity will cause the water to fill until electrolyte solution contacts the full level detector 224. Should the water supply be empty then the cell 140 will not restart until it is refilled, causing the engine to return to normal operation. Once the added water brings the electrolyte solution level up to contact the full level, a ground to C2-86 powering C2-87 and signaling the CPU occurs start cell 140 if all other conditions are in compliance.

At the same time the CPU will turn off both solenoids 218 and 210, stopping the fill process and turn on the power supply to e.g. to anode 206. When cell 140 has been running two hours or more it can take about two hours for the evolved gases to leave and lower the electrolyte solution level.

Two hours after shutdown, low and full level detectors 226 and 224 are connected to ground. This causes the nickel rods to be cleaned and brings the cell into a neutral state.

Cell Condenser Operation

The evolved gas vented during the fill cycle for cell 140 is passed through cell condenser 148 which forces some trapped moisture back to cell 140 through pressure equalization such as via hose 152. No evolved gas is wasted. It is routed to the engine through the check valve 230. Other trapped moisture in the condenser cell 148 will return to the cell 140 through gravity and shutdown

Should the condenser cell 148 fill with electrolyte solution for any reason, the solution will come into contact with level detector 150 that will stop the electrolysis cell 140. The CPU stops power to the cell 140. For safety purposes, cell 140 in this situation can only be restarted by trained personnel as solution should not collect in the cell condenser.

It has been observed that even when attached to the cell 140 with a non-conductive means (e.g. nylon fittings, plastic hose) the evolving gas gives cell condenser 148 an electric charge. Cell condenser 148 is therefore grounded, preventing accidental static ignition of the evolved gas and providing a ground for the level detector 150. As noted previously herein fan 158 is mounted across from the cell condenser to pass outside (ambient) air to bring the evolving gas to a dew point in any environment.

Exhaust Water Process

When running, if the level system 134 on the water tank 132 detects low water during a fill cycle for cell 140 or after start up, the water from the exhaust capture system initiates a water tank fill/top up. This water tank fill process will not start unless level system 120 detects water in the water condenser 116.

When level system 134 on the water tank 132 registers low level, 3-way solenoid 108 between the exhaust gas condenser 108 and the water condenser 116 powers on, closing off the condenser 116 and sending exhaust gas to the engine intake through the hydrogen and oxygen gas output hose 154 via 112. Alternatively, solenoid 108 could just close and stop the exhaust gas from moving through to line 112 and back to the intake via line 154

Gas water tank 2-way solenoid 110 is closed to permit the water condenser 116 to be pressurized (via pressure connection 144). In unison, the gas feed solenoid 146 feeding cell condenser 148 closes (powers on), allowing pressure to build up in the water condenser 116 as detected by sensor 118. Pressure may also build in cell 140.

When the pressure in the water condenser 116 reaches a turn on state the 3-way solenoid 124 on the filter assembly 126,128,130 opens (powers on), allowing distilled water in condenser 116 to be pushed through the filter system into the water tank 132. It is understood that solenoid 122 is normally open in a position to pass water toward solenoid 124. Once the water tank 132 fill is achieved (detected by level system 134) or pressure driving water from condenser 116 drops below a certain point, the filter system solenoid 124 turns off along with the gas feed solenoid 146 opening cell 140 to the cell condenser 148.

If the cell 140 can be filled, then normal operation resumes. If not then operations may be repeated, for example once pressure is sufficient, or water is made and available in water condenser 116.

To capture water, the 3-way solenoid 108 between the exhaust condenser 106 and water condenser 116 collection opens (powers off) to direct the exhaust into water condenser 116, while solenoid 110 opens to output the exhaust from hose 114 112 and on to 154 to mix with the evolved gases.

Should the water tank 116 get too full, the level system 120 in the water condenser 116 will (power on) the 3-way drain solenoid 122 between the water condenser 116 and the filter system solenoid 124, bringing it to the correct level. When freezing temperatures are detected, the filter system (126-132) and water condenser 116 will drain on shutdown to prevent filter damage. As the filter system like system 500 may also be coupled to water tank 132 in a manner which permits backflow, water from tank 132 may also be drained on shut.

In an alternative water capture system, engines with air conditioning condensate can be configured to capture and direct condensate to water tank 132. In this way only a charcoal filter may be used.

It will be apparent those of skill in the art that various systems, apparatus methods, etc are disclosed herein including the following examples.

There is provided an apparatus to change the temperature of a fluid comprising: a body (e.g. metal or conductive ceramic) forming a passage to receive a fluid through the body; and at least one Peltier-type thermocouple mounted to the body in the passage, the Peltier-type thermocouple having a hot side and a cold side over which the fluid passes. Each of the at least one Peltier-type thermocouple may be a) mounted hot side in against the body and the fluid passes over the cold side or b) mounted code side in against the body and the fluid passes over the hot side. The at least one Peltier-type thermocouple may be mounted using a thermo compound adhesive. The at least one Peltier-type thermocouple may be mounted to surround at least a segment of the passage. The apparatus may be provided within or adjacent a water tank such that there is provided a water tank comprising a water feed passage to supply water from the tank and an apparatus to change the temperature of a fluid as described where, the apparatus is in fluid communication with the water feed passage. Similarly an apparatus as described may be provided with a gas condenser unit having a vessel with a gas feed passage to supply gas from the vessel. The apparatus may be in fluid communication with the gas feed passage. In one example, apparatus is configured with the cold side in to heat the water from the water tank. In one example, the apparatus is configured with the hot side in to cool the gas from the gas condenser.

In one example, there is a method for heating water in the water tank or feed line comprising providing power to at least one Peltier type thermocouple mounted cold side in to a body providing a passage through which the water passes such that the water passes over a hot side of the Peltier type thermocouple. The power may be obtained from a plurality of Peltier type thermocouples mounted about the electrolysis cell, utilizing heat generated by the operations of the cell to produce a sufficient temperature differential across the Peltier devices when the cell is generating gases from the electrolytic solution. The water may be selectively heated when the ambient temperature is below a certain threshold (e.g. −10° C.).

In one example there is a method to cool engine gases comprising providing power to at least one Peltier type thermocouple mounted hot side in to a body providing a passage through which the gases pass such that the gases pass over a cold side of the Peltier type thermocouple. The power may be obtained from a plurality of Peltier type thermocouples mounted about the electrolysis cell, utilizing heat generated by the operations of the cell to produce a sufficient temperature differential across the Peltier devices when the cell is generating gases from the electrolytic solution.

There is provided a method for generating combustion enhancing gases for an internal combustion engine comprising: generating the combustion enhancing gases using an electrolysis cell having an electrolytic solution, the cell in fluid communication with a gas conduit to provide the combustion enhancing gases to an intake of the engine; capturing water using a water capturing system; storing the water from the water capturing system; and selectively providing the water to the electrolysis cell to replenish the electrolytic solution. Selectively providing the water may comprise dosing an output of combustion enhancing gases from the cell and opening a water fill tube for the cell.

The method may comprise detecting using a plurality of electrical detectors an amount of electrolytic solution in the cell and providing the water in response to the amount detected. The method may comprise not generating the combustion enhancing gases in response to the amount detected (by not providing power to an electrode of the). The method may comprise detecting an amount of water in a water tank storing water from the water capture system and selectively activating the water capture system to provide additional water to replenish the water tank. To provide additional water may comprise feeding a positive pressure from the electrolysis cell to the water capture system to drive water to the water tank. The method may comprise filtering the water from the water capture system. The method may comprise selectively capturing water from the exhaust. The method may comprise receiving exhaust gases from an engine manifold of the engine, cooling and condensing the exhaust gases to obtain water and returning the exhaust gases to the intake.

The method may comprise, before providing the combustion enhancing gases to the intake, condensing the combustion enhancing gases received from the cell in a cell condenser to obtain water and/or electrolytic fluid therefrom and returning such water and/or electrolytic fluid to the cell.

It will be appreciated by those of ordinary skill in the art that the matter can be embodied in other specific forms without departing from the spirit of essential character thereon.

What is claimed:

1. An engine exhaust water recovery system comprising:
an exhaust receiving and cooling segment configured for fluid coupling to an exhaust manifold to receive exhaust gas from an engine;
an exhaust water condensing unit in selective fluid coupling with the exhaust receiving and cooling segment to selectively receive exhaust gas;
an exhaust discharging segment in selective fluid coupling with the exhaust receiving and cooling segment and the exhaust condensing unit to selectively receive exhaust gas for discharge from the engine exhaust water recovery system; and
a control unit to control the selective receiving of exhaust gas to produce water in the exhaust condensing unit.

2. The engine exhaust water recovery system of claim 1 wherein the exhaust discharging segment is configured for fluid coupling with an intake of the engine to discharge the exhaust gas back to the engine.

3. The engine exhaust water recovery system of claim 1 wherein the exhaust water condensing unit comprises a water feed passage to discharge water condensed by the exhaust condensing unit.

4. The engine exhaust water recovery system of claim 3 wherein the exhaust water condensing unit comprises a fluid inlet configured for fluid coupling to a evolving gas outlet of an electrolysis cell generating combustion enhancing gas, the combustion enhancing gas pressurizing the exhaust condensing unit to discharge water through the water feed passage under control of the control unit.

5. The engine exhaust water recovery system of claim 4 wherein the water feed passage is in fluid coupling with a water tank to store water to feed the electrolysis system.

6. The engine exhaust water recovery system of claim 5 wherein the water feed passage discharges the water to a filtration system to filter the water for the water tank.

7. The engine exhaust water recovery system of claim 1 having a first solenoid to selectively control, via the control unit, a delivery of exhaust gas from the exhaust receiving and cooling segment to the exhaust water condensing unit.

8. The engine exhaust water recovery system of claim 7 having a second solenoid to selectively control, via the control unit, a delivery of exhaust gas from the exhaust water condensing unit to the exhaust discharging segment.

9. The engine exhaust water recovery system of claim 1 having a drain in selective fluid communication with the water feed passage of the exhaust water condenser unit and a third solenoid to selectively control, via the control unit, a discharge of water from the exhaust water condensing unit through the drain.

10. The engine exhaust water recovery system wherein the exhaust condensing unit comprises a level detector, in communication with the control unit, to detect a level of water in the exhaust water condensing unit.

11. The engine exhaust water recovery system of claim 1 wherein the exhaust receiving and cooling segment comprises a stainless steel pipe having a coiled portion.

12. The engine exhaust water recovery system of claim wherein the exhaust receiving and cooling segment comprises a stainless steel pipe with an engine mounting end for fluid coupling to the exhaust manifold using a brass fitting.

13. A system for producing one or more gases for enhancing combustion in an internal combustion engine, said engine having an intake, the system comprising:
an electrolysis cell, to generate one or more combustion enhancing gases from an electrolytic solution;
a gas conduit, to connect the electrolysis cell to the intake of the internal combustion engine;
a water tank, having a tank discharge port in fluid coupling with the electrolysis cell, to hold water to replenish the electrolysis cell;
a water recovery system, in fluid coupling with the water tank, to generate water to replenish the water in the water tank; and
a control unit to control power to the electrolysis cell to control the generating of the one or more combustion enhancing gases, and to control the respective replenishment of water by water tank and the water recovery system.

14. The system of claim 13 wherein the water recovery system is an engine exhaust water recovery system in fluid coupling with an exhaust manifold of the internal combustion engine.

15. The system of claim 14 comprising a pressure connection between the electrolysis cell and the engine exhaust water recovery system wherein a positive pressure from the one or more combustion enhancing gases selectively drives water from the engine exhaust water recovery system to replenish the water tank under control of the control unit.

16. The system of claim 14 wherein the engine exhaust water recovery system is in fluid coupling with the gas conduit to provide exhaust gas with the combustion enhancing gases to the intake.

17. The system of claim 13 wherein the electrolysis cell has a level detection system in communication with the control unit to control an operation of the electrolysis cell, including to replenish water.

18. The system of claim 17 wherein the level detection system comprises a plurality of level detectors extending into the electrolysis cell, through a top of the cell, and to respective lengths below the top, the plurality of level detectors each electrically detecting a respective amount of the electrolytic solution in the electrolysis cell using electrical current.

19. The system of claim 18 wherein at least one of the level detectors comprises a wire having a diode and a terminal.

20. The system of claim 19 wherein the wire is over moulded with a plug in sealing engagement with the wire, the plug configured to fasten the level detector to the top of the cell.

21. The system of claim 20 wherein the level detectors are electrically coupled to automotive relays to provide respective level signals to the control unit.

22. The system of claim 13 further comprising a cell condenser, in fluid communication with the electrolysis cell and the gas conduit, to condense electrolytic fluid from the combustion enhancing gases and return the electrolytic fluid to the electrolysis cell.

23. The system of claim 13 wherein the electrolysis cell comprises:
first electrode comprising a cylindrical body;
a second electrode comprising a cylindrical body within the first electrode; and
a first electrode extension electrically coupled to the first electrode and coiled about and spaced from the second electrode.

24. The system of claim 23 wherein the electrode extension and second electrode comprise mesh bodies of expanded metal.

25. The system of claim 23 wherein the electrolysis cell further comprises a top cap and a bottom cap in sealing engagement about ends of the first electrode to define a containment body for the electrolytic solution.

26. The system of claim 23 further comprising insulating spacers separating the coils of the first electrode extension and separating the first electrode extension from the second electrode.

27. The system of claim 13 wherein the water tank comprises a filter system to filter the water received from the water recover system.

28. The system of claim 27 wherein the filter system comprises a series of filters defining a replaceable cartridge.

29. The system of claim 13 wherein the water tank is positioned vertically above the electrolysis cell to replenish the cell via a gravity feed line.

30. The system of claim 29 comprising at least one Peltier-type thermocoupling adjacent the water tank to heat the discharge port and/or the gravity feed line.

31. The system of claim 29 comprising a plurality of Peltier-type thermocouplings mounted about the electrolysis cell to generate power from heat generated by the electrolysis cell.

32. The system of claim 31 wherein the plurality of Peltier-type thermocouplings mounted about the electrolysis cell are electrically coupled to provide power to the at least one Peltier-type thermocoupling adjacent the water tank for heating.

33. An electrolysis cell, to generate gases from an electrolytic solution, comprising:
a first electrode comprising a cylindrical body;
a second electrode comprising a cylindrical body within the first electrode; and
a first electrode extension electrically coupled to the first electrode and coiled about and spaced from the second electrode.

34. The electrolysis cell of claim 33 wherein the electrode extension and second electrode comprise mesh bodies of expanded metal.

35. The electrolysis cell of claim 33 further comprising insulating spacers separating the coils of the first electrode extension and separating the first electrode extension from the second electrode.

36. The electrolysis cell of claim 33 further comprising a top cap and a bottom cap in sealing engagement about ends of the first electrode to define a containment body for the electrolytic solution.

37. The electrolysis cell of claim 36 further comprising a plurality of level detectors extending into the electrolysis cell and to respective lengths below the top cap, the plurality of level detectors each electrically detecting a respective amount of the electrolytic solution in the electrolysis cell using electrical current.

38. The electrolysis cell of claim 37 wherein at least one of the level detectors comprises a wire having a diode and a terminal.

39. The electrolysis cell of claim 38 wherein the wire is over moulded with a plug in sealing engagement with the wire, the plug configured to fasten the level detector to the top of the cell.

40. The electrolysis cell of claim 36 comprising a water fill tube extending into the containment body and configured for coupling to a feed line to selectively receive water to replenish the electrolytic solution.

41. The electrolysis cell of claim 40 comprising a primary outlet and a vent outlet to a cell condenser, wherein the primary outlet is selectively open and the vent outlet selectively closed under normal operation of the electrolysis cell to provide gases to the cell condenser and wherein the primary outlet is selectively closed and the vent outlet selectively open to receive water to replenish the electrolytic solution.
